(19) United States
(12) Patent Application Publication
(10) Pub. No.: US 2015/0364426 A1
(43) Pub. Date: Dec. 17, 2015

(54) DECOUPLING CAPACITOR FOR SEMICONDUCTORS

(71) Applicant: GLOBALFOUNDRIES Inc., Grand Cayman (KY)

(72) Inventors: Jagar Singh, Clifton Park, NY (US); Jerome Ciavatti, Ballston Lake, NY (US); Anurag Mittal, Saratoga Springs, NY (US); Manfred Eller, Beacon, NY (US)

(21) Appl. No.: 14/303,714

(22) Filed: Jun. 13, 2014

(51) Int. Cl. H01L 23/538; H01L 23/66; H01L 29/06; H01L 27/06; H01L 29/94; H01L 27/08

(52) U.S. Cl. CPC H01L 23/5386; H01L 29/94; H01L 27/0805; H01L 29/0653; H01L 27/0629; H01L 23/66; H01L 2223/6666

(57) ABSTRACT

Embodiments of the present invention provide an improved decoupling capacitor structure. A contact region is disposed over a source/drain region of the decoupling capacitor structure. Each contact region is formed as a plurality of segments, wherein an inter-segment gap separates a segment of the plurality of segments from an adjacent segment of the plurality of segments. Embodiments may include multiple contact regions between two gate regions. Arrays of decoupling capacitors may arranged as an alternating “checkerboard” pattern of P-well and N-well structures, and may be oriented at a diagonal angle to a metallization layer to facilitate connections of multiple decoupling capacitors within the array.

### FIELD OF THE INVENTION

The present invention relates generally to semiconductor fabrication, and more particularly, to the fabrication of decoupling capacitors in semiconductor integrated circuits.

### BACKGROUND

Decoupling capacitors (“de-caps”) are an integral part of power distribution network design processes. Miniaturization of chips has significantly increased requirements of the on-chip power and ground distribution network. As a result, the on-chip current densities increase. The higher switching speed of the smaller transistor produces a faster current transient in the network. De-caps are widely used to manage the power supply noise. De-caps can have a significant impact on characteristics (i.e. speed, cost, and power) of integrated circuits. Therefore, it is desirable to have improvements in decoupling capacitors for semiconductor integrated circuits.

### SUMMARY

Embodiments of the present invention provide an improved decoupling capacitor structure. Contact regions are formed as multi-segmented contact strips with an inter-segment gap between segments. This improves the manufacturability of the contact regions, as the etch process is more controllable, preventing gouging of nearby epitaxial regions. Embodiments may include multiple contact regions between two gate regions to reduce contact resistance, thereby improving device performance and providing redundancy to improve product yield. Arrays of decoupling capacitors are arranged as an alternating checkerboard pattern of P-well and N-well structures, and may be oriented at a diagonal angle to a metallization layer to facilitate connections of multiple decoupling capacitors within the array.

In a first aspect, embodiments of the present invention include a semiconductor structure comprising a semiconductor substrate; a first gate formed on the semiconductor substrate; a first source/drain region formed in the semiconductor substrate adjacent to the first gate; a second source/drain region formed in the semiconductor substrate adjacent to the first gate; the first source/drain region and the second source/drain region being in electrical contact with each other; and a first contact region, formed as a first plurality of segments, is disposed over the first source/drain region, with a first inter-segment gap separating a segment of the first plurality of segments from an adjacent segment of the first plurality of segments.

In a second aspect, embodiments of the present invention include a semiconductor structure comprising: an array comprising a plurality of capacitor structures formed on a semiconductor substrate and arranged in an alternating pattern comprising a first capacitor type and a second capacitor type. The first capacitor type and second capacitor type each comprise: a first gate formed on the semiconductor substrate; a first source/drain region formed in the semiconductor substrate adjacent to the first gate; a second source/drain region formed in the semiconductor substrate adjacent to the first gate, the first source/drain region and the second source/drain region being in electrical contact with each other; a first contact region, formed as a first plurality of segments, disposed over the first source/drain region, with a first inter-segment gap separating a segment of the plurality of segments from an adjacent segment of the first plurality of segments. The first capacitor type comprises an N-type work function metal, and an N-well region disposed below the first gate. The second capacitor type comprises a P-type work function metal, and a P-well region disposed below the second gate.

In a third aspect, embodiments of the present invention include an array comprising a plurality of capacitor structures formed on a semiconductor substrate and arranged in an alternating pattern comprising a first capacitor type and a second capacitor type. The first capacitor type and second capacitor type each comprise: a first gate formed on the semiconductor substrate; a first source/drain region formed in the semiconductor substrate adjacent to the first gate; a second source/drain region formed in the semiconductor substrate adjacent to the first gate, wherein the first source/drain region and the second source/drain region are in electrical contact with each other; a first contact region, formed as a first plurality of segments, disposed over the first source/drain region with a first inter-segment gap separating a segment of the first plurality of segments from an adjacent segment of the first plurality of segments. The first capacitor type comprises an N-type work function metal and an N-well region disposed below the first gate; and the second capacitor type comprises a P-type work function metal, and a P-well region disposed below the second gate. At least one row or column of the array is comprised of dummy capacitor structures.

### BRIEF DESCRIPTION OF THE DRAWINGS

The accompanying drawings, which are incorporated in and constitute a part of this specification, illustrate several embodiments of the present teachings and together with the description, serve to explain the principles of the present teachings. Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity. Furthermore, for clarity, some reference numbers may be omitted in certain drawings.

FIG. 1 shows a side view of an N-well decoupling capacitor in accordance with embodiments of the present invention.

FIG. 2 shows a side view of a P-well decoupling capacitor in accordance with embodiments of the present invention.

FIG. 3 shows a top-down view of a decoupling capacitor in accordance with embodiments of the present invention.

FIG. 4 shows a top-down view of an additional embodiment of a decoupling capacitor in accordance with embodiments of the present invention.

FIG. 5 shows a top-down view of yet another additional embodiment of a decoupling capacitor in accordance with embodiments of the present invention.

FIG. 6 shows a decoupling capacitor array in accordance with embodiments of the present invention.

FIG. 7 shows a decoupling capacitor array in accordance with alternative embodiments of the present invention.

### DETAILED DESCRIPTION

Illustrative embodiments will now be described more fully herein with reference to the accompanying drawings, in which embodiments are shown. This disclosure may, however, be embodied in many different forms and should not be construed as limited to the embodiments set forth herein. Rather, these embodiments are provided so that this disclosure will be thorough and complete and will fully convey the scope of this disclosure to those skilled in the art. In the description, details of well-known features and techniques may be omitted to avoid unnecessarily obscuring the presented embodiments.

Embodiments of the present invention provide an improved decoupling capacitor structure. Contact regions are formed as multi-segmented contact strips with an inter-segment gap between them. Embodiments may include multiple contact regions between two gate regions to reduce contact resistance, thereby improving device performance and providing redundancy to improve product yield. Arrays of decoupling capacitors are arranged as an alternating checkerboard pattern of P-well and N-well structures, and may be oriented at a diagonal angle to a metallization layer to facilitate connections of multiple decoupling capacitors within the array.

The terminology used herein is for the purpose of describing particular embodiments only and is not intended to be limiting of this disclosure. As used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. The term “set” is intended to mean a quantity of at least one. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” “some embodiments,” or similar language means that a particular feature, structure, or characteristic described in connection with the embodiment is included in at least one embodiment of the present invention. Thus, appearances of the phrases “in one embodiment,” “in an embodiment,” “in embodiments”, “in some embodiments”, and similar language throughout this specification may, but do not necessarily, all refer to the same embodiment. Additionally, one or more features of an embodiment may be “mixed and matched” with features of another embodiment.

The terms “overlying” or “atop”, “positioned on”, “positioned atop”, or “disposed on”, “underlying”, “beneath” or “below” mean that a first element, such as a first structure (e.g., a first layer) is present on a second element, such as a second structure (e.g. a second layer) wherein intervening elements, such as an interface structure (e.g. interface layer) may be present between the first element and the second element.

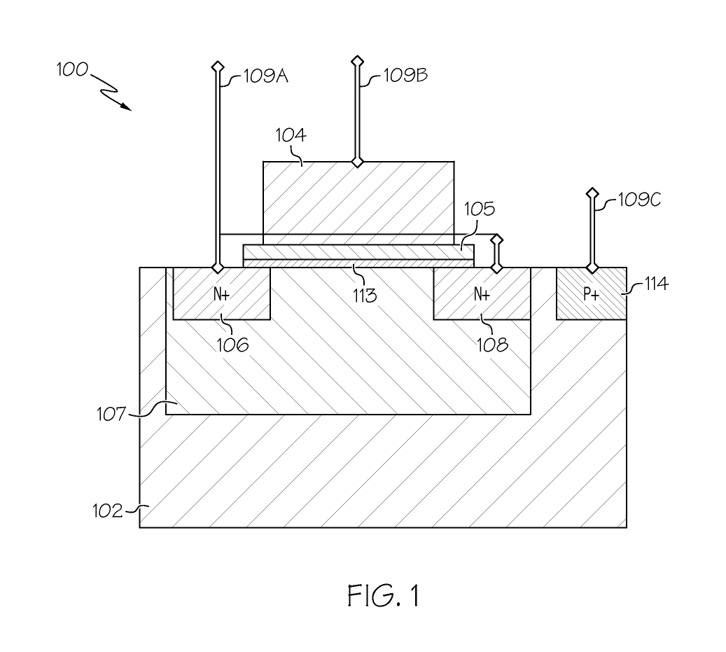

FIG. 1 shows a side view of an N-well decoupling capacitor 100 in accordance with embodiments of the present invention. A semiconductor substrate 102 has a gate 104 formed thereon. Below the gate 104 may be a work function metal 105. In some embodiments, the work function metal is an N-type work function metal (nWf). The nWf may include titanium aluminum (TiAl) and/or another suitable material. A gate dielectric layer 113 may be disposed below the work function metal 105. In some embodiments, the semiconductor substrate 102 comprises an N-well region 107 disposed below the gate 104. The N-well may be doped with arsenic, phosphorus, or another suitable material. A first source/drain region 106 and a second source/drain region 108 may be formed in the substrate 102 adjacent to the gate 104. The first source/drain region 106 and the second source/drain region 108 may be in electrical contact with one another via any suitable mechanism, including, but not limited to, metallization layers, local interconnects, and silicide formations. In some embodiments, the capacitor terminals may include those shown at 109A and 109B. In other embodiments, one of the capacitor terminals may instead include 109C, which is electrically connected to a P+ region 114 of substrate 102.

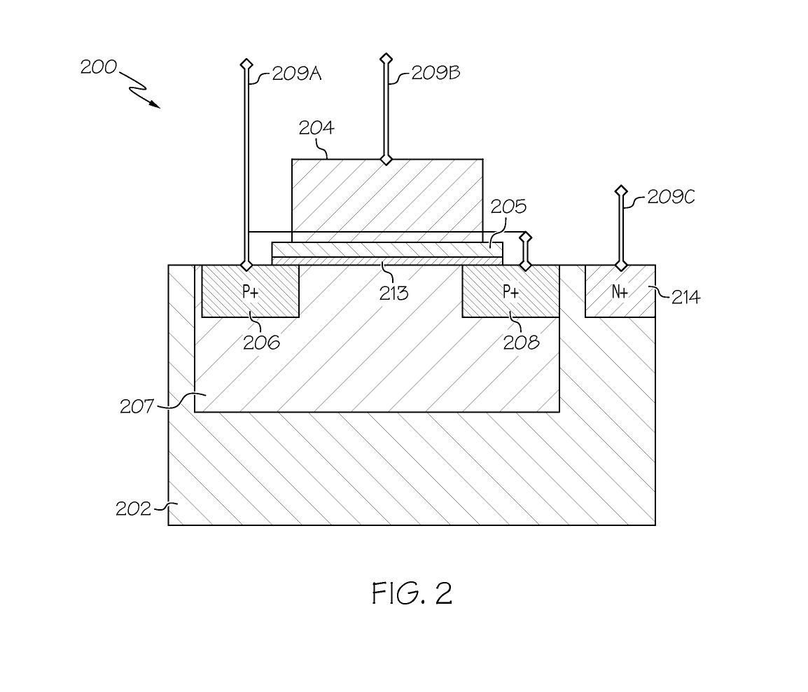

FIG. 2 shows a side view of a P-well decoupling capacitor 200 in accordance with embodiments of the present invention. A semiconductor substrate 202 has a gate 204 formed thereon. In some embodiments, the semiconductor substrate 202 comprises a P-well region 207 disposed below the gate 204. Below the gate 204 may be a work function metal 205. In some embodiments, the work function metal is a P-type work function metal (pWf). A gate dielectric layer 213 may be disposed below the work function metal 205. The P-well may be doped with boron and/or another suitable material. The pWf may include titanium nitride (TiN), tantalum nitride (TaN), aluminum nitride (AlN), or any other suitable material. A first source/drain region 206 and a second source/drain region 208 may be formed in the substrate 202 adjacent to the gate 204. The first source/drain region 206 and the second source/drain region 208 are in electrical contact with each other. In some embodiments, the capacitor terminals may include those shown at 209A and 209B. In other embodiments, one of the capacitor terminals may instead include 209C, which is electrically connected to a N+ region 214 of substrate 202. In addition to the embodiments described in FIG. 1 and FIG. 2, embodiments of the present invention may also include an N-type work function metal over a substrate comprising a P-well region, and/or a P-type work function metal over a substrate comprising an N-well region.

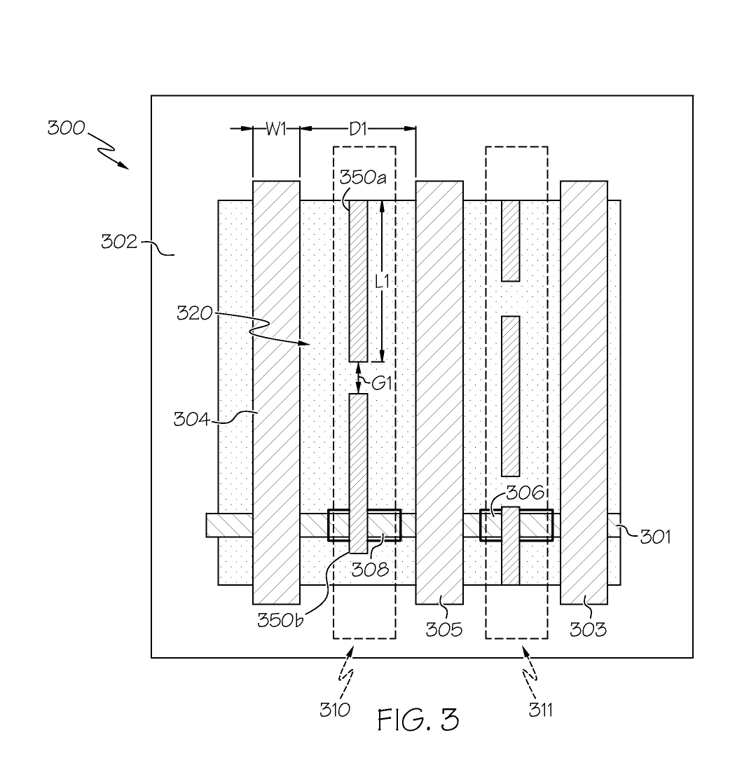

FIG. 3 shows a top-down view of a decoupling capacitor 300 in accordance with embodiments of the present invention. A semiconductor substrate 302 may have a first gate 304 and a second gate 305 formed thereon, and an active region 320. Each of the gates 304 and 305 has a width, W1. In some embodiments, W1 may range from about 40 nanometers to about 200 nanometers. In some embodiments, gates 304 and 305 may have the same width or different widths. A distance between the first gate 304 and the second gate 305 is D1. In some embodiments, D1 may range from about 60 nanometers to about 250 nanometers. For clarity, only one fin 301 is shown here, but in practice more fins may be present. The gates 304 and 305 may be formed by a replacement metal gate process or another suitable process. A first source/drain region 306 and a second source/drain region 308 may be formed in the substrate 302 adjacent to the gate 304. The first source/drain region 306 and the second source/drain region 308 may be in electrical contact with each other (as shown schematically in FIG. 1 and FIG. 2). A first contact region 310 may be formed between the first gate 304 and the second gate 305 as a plurality of segments (for example, segments 350a and 350b), with each segment of the plurality of segments separated from an adjacent segment by an inter-segment gap G1. In some embodiments, G1 may range from about 20 nanometers to about 300 nanometers. In some embodiments, G1 may range from about 20 nanometers to about 300 nanometers. In some embodiments, G1 may range from about 15 nanometers to about 250 nanometers. In some embodiments, G1 may range from about 35 nanometers to about 500 nanometers. In some embodiments, the length of the gaps may be equal, and in some embodiments, the length of the gaps may be different from one another. In some embodiments, the length of a segment may be L1. In some embodiments, L1 ranges from about 80 nanometers to about 500 nanometers. In some embodiments, L1 may range from about 30 nanometers to about 400 nanometers. In some embodiments, L1 may range from about 30 nanometers to about 1000 nanometers. In some embodiments, L1 may range from about 80 nanometers to about 1000 nanometers. In some embodiments, L1 may range from about 80 nanometers to about 1200 nanometers. In some embodiments, the length of the segments may be equal, and in some embodiments, the length of the segments may be different from one another. The breaking up of the contact region into segments, as provided by the present invention, allows for better control of etching since smaller segments are etched as compared to larger un-segmented contact regions. The smaller segments enable a more controllable etch. This results in improved product yield and/or device performance. It also reduces unwanted gouging of nearby epitaxial regions. In some embodiments, a second contact region 311 is disposed between the second gate 305 and a third gate 303.

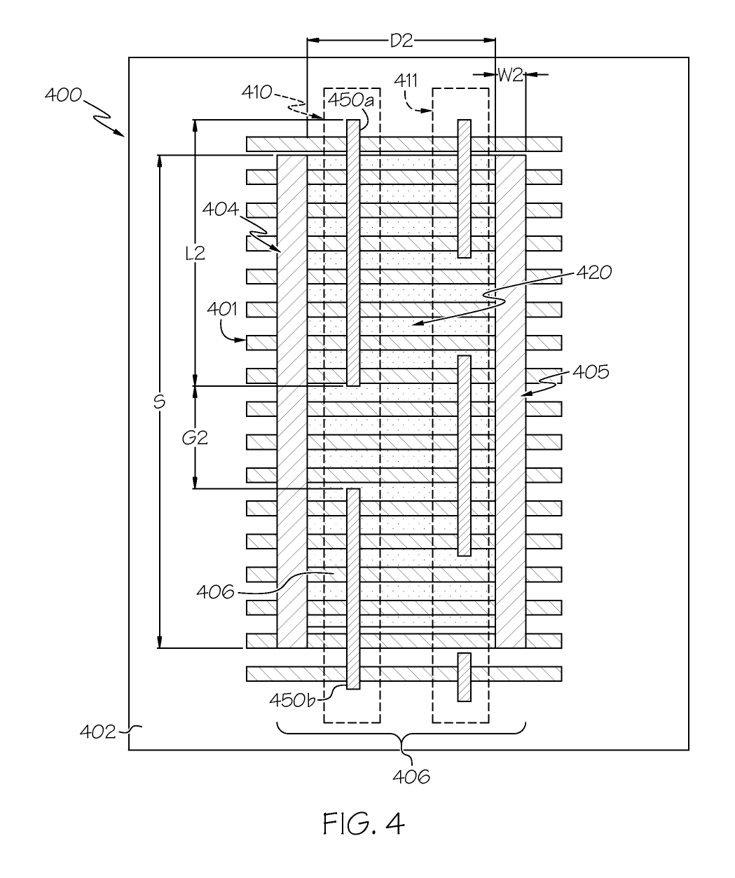

FIG. 4 shows a top-down view of an additional embodiment of a decoupling capacitor 400 in accordance with embodiments of the present invention. A semiconductor substrate 402 may have a first gate 404 and a second gate 405 formed thereon, and an active region 420. Each of the gates 404 and 405 has a width W2. In some embodiments, W2 may range from about 40 nanometers to about 250 nanometers. In some embodiments, the width of the gates 404 and 405 may be equal, and in some embodiments, the width of the gates 404 and 405 may be different from one another. Each of the gates 404 and 405 has a length S. In some embodiments, S may range from about 250 nm to about 500 nm. In some embodiments, S may range from 250 nm to about 5000 nm. A distance between the first gate 404 and the second gate 405 is D2. In some embodiments, D2 may range from about 60 nanometers to about 120 nanometers. Fins are shown as reference 401. A source/drain region is the section formed in the fins 401 between gate 404 and gate 405, and is indicated generally as reference number 406. In this embodiment, two contact regions (410 and 411) are disposed between the first gate 404 and the second gate 405. A first contact region 410 and a second contact region 411 may be disposed over the source/drain region 406. Each of the first contact region 410 and the second contact region 411 may be formed as a plurality of segments (for example, segments 450a and 450b in the first contact region 410), with each segment of the plurality of segments having an inter-segment gap G2 that separates it from an adjacent segment. In some embodiments, the length of the gaps may be equal, and in some embodiments, the length of the gaps may be different from one another. In some embodiments, G2 may range from about 20 nanometers to about 200 nanometers. In some embodiments, G2 may range from about 20 nanometers to about 300 nanometers. In some embodiments, G2 may range from about 15 nanometers to about 250 nanometers. In some embodiments, G2 may range from about 35 nanometers to about 500 nanometers. Each of the segments has a length L2. In some embodiments, L2 may range from about 30 nanometers to about 400 nanometers. In some embodiments, L2 may range from about 30 nanometers to about 1000 nanometers. In some embodiments, L2 may range from about 80 nanometers to about 1000 nanometers. In some embodiments, L2 may range from about 80 nanometers to about 1200 nanometers. In some embodiments, the length of the segments may be equal, and in other embodiments, the length of the segments may be different from one another. In some embodiments, the inter-segment gap of the first contact region 410 is staggered in a non-overlapping configuration with an inter-segment gap of the second contact region 411. Embodiments of the present invention may utilize a design rule to prevent partial overlap of a contact region on a fin and to ensure every fin is in contact with at least one segment. This is to reduce the risk of early oxide breakdown, which can cause reliability issues.

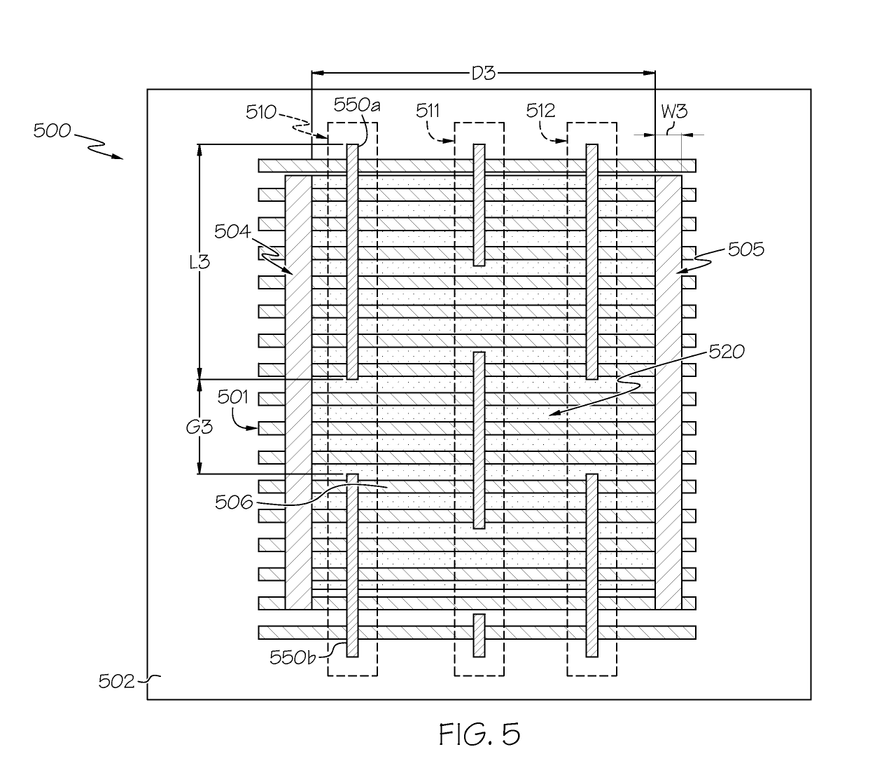

FIG. 5 shows a top-down view of a decoupling capacitor 500 in accordance with embodiments of the present invention. A semiconductor substrate 502 has a first gate 504 and a second gate 505 formed thereon, and an active region 520. Each of the gates 504 and 505 has a width W3. In some embodiments, W3 may range from about 40 nanometers to about 2000 nanometers. In some embodiments, the widths of the gates may be equal, and in some embodiments, the widths may be different from one another. A distance between the first gate 504 and the second gate 505 is D3. In some embodiments, D3 may range from about 100 nanometers to about 200 nanometers. Fins are shown as reference number 501. A source/drain region is the section formed in the fins 501 between gate 504 and gate 505, and is indicated generally as reference number 506. A first contact region 510, a second contact region 511, and a third contact region 512 may be disposed over the source/drain region 506, such that three contact regions are disposed between the first gate 504 and the second gate 505. Each of the first contact region 510, the second contact region 511, and the third contact region 512 is formed as a plurality of segments (for example, segments 550a and 550b of the first contact region 510), with each segment of the plurality of segments having an inter-segment gap G3 that separates it from an adjacent segment. In some embodiments, the inter-segment gap of the first contact region 510 is staggered in a non-overlapping configuration with the inter-segment gap of the second contact region 511. In some embodiments, G3 may range from about 20 nanometers to about 300 nanometers. In some embodiments, G3 may range from about 20 nanometers to about 300 nanometers. In some embodiments, G3 may range from about 15 nanometers to about 250 nanometers. In some embodiments, G3 may range from about 350 nanometers to about 500 nanometers. In some embodiments, the length of the gaps may be equal, and in some embodiments, the length of the gaps may be different from one another. Each of the segments has a length L3. In some embodiments, L3 may range from about 30 nanometers to about 400 nanometers. In some embodiments, L3 may range from about 30 nanometers to about 1000 nanometers. In some embodiments, L3 may range from about 80 nanometers to about 1000 nanometers. In some embodiments, L3 may range from about 80 nanometers to about 1200 nanometers. In some embodiments, the length of the segments may be equal, and in some embodiments, the length of the segments may be different from one another.

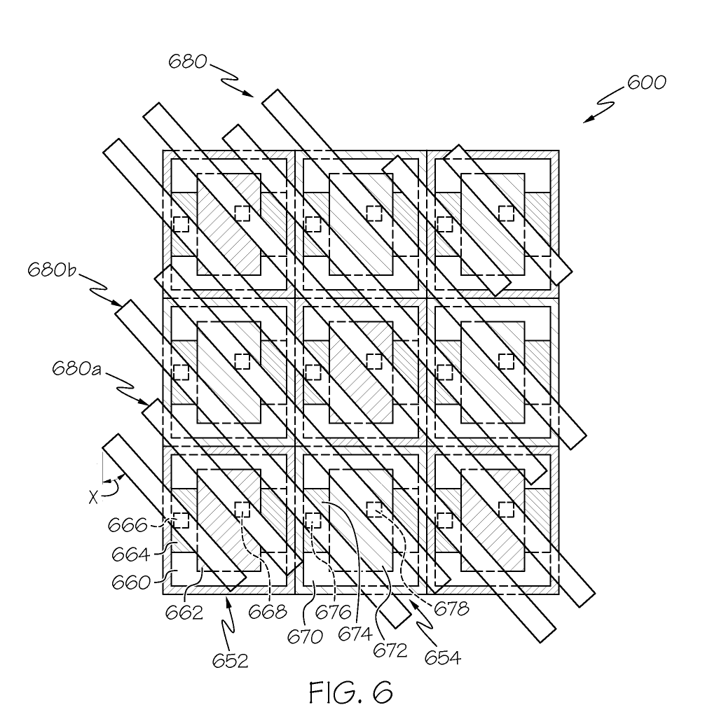

FIG. 6 shows a decoupling capacitor array 600 in accordance with embodiments of the present invention. The array 600 may include a plurality of capacitor structures formed on a semiconductor substrate and arranged in an alternating pattern, like a “checkerboard”, comprising a set (at least one) of capacitors 652 of a first capacitor type and a set (at least one) of capacitors 654 of a second capacitor type. In this checkerboard fashion, each capacitor of the first type is adjacent at each of its sides to other capacitors of the second type (rather than of the first type). Likewise, each capacitor of the second type are adjacent at each of its sides only to capacitors of the first type (rather than the second type). In some embodiments, the first capacitor type is N-type, and the second capacitor type is P-type. This alternating pattern helps maintain an adequate chemical mechanical polish (CMP) process because CMP becomes challenging if a contiguous material region is too large. As shown in FIG. 6, decoupling capacitor 652 has an N-well 660, N-type gate 662, and an active region 664, source drain contact 666, and a gate contact 668. Decoupling capacitor 654 has a P-well 670, P-type gate 672, active region 674, source drain contact 676, and gate contact 678. In some embodiments, the array may comprise a plurality of metallization lines 680 oriented at a diagonal angle to the gate of the capacitors of the array. A first metallization line 680a of a plurality of metallization lines 680 may be oriented at a diagonal angle X to the N-type gates 662. The first metallization line 680a may attach to at least one of the N-type gates 662 via at least one gate contact, such as that shown at reference number 668. A second metallization line 680b of the plurality of metallization lines 680 may attach to at least one of the P-type active regions 674 via at least one source drain contact such as that shown at reference number 676. In some embodiments, the diagonal angle X is a 45 degree angle, but any other suitable measurement may be substituted without parting from the scope of the invention.

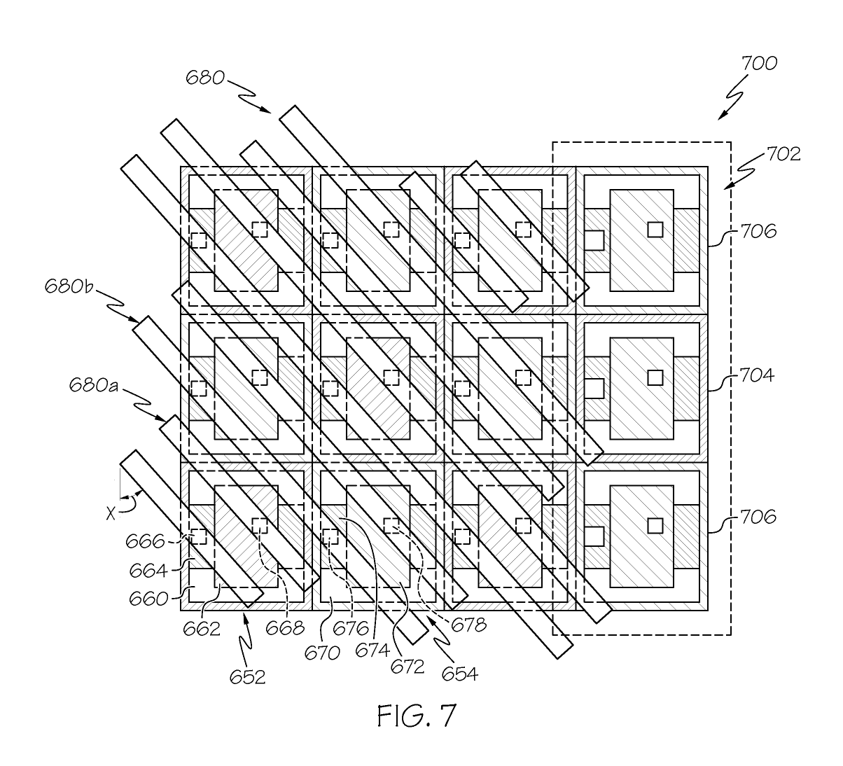

FIG. 7 shows a decoupling capacitor array 700 in accordance with alternative embodiments of the present invention. Array 700 is similar to array 600 of FIG. 6, but includes a “dummy” column (or row) 702 of at least one capacitor structure 704 of a first capacitor type and at least one capacitor structure 706 (two such structures 706 shown in FIG. 7) of a second capacitor type. These structures are not typically electrically connected to the rest of the array. They are used to handle edge boundary conditions, so that any inconsistencies in fabrication along a boundary are not included in the functional capacitor circuit.

While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

What is claimed is:

1. A semiconductor structure comprising:
a semiconductor substrate;
a first gate formed on the semiconductor substrate;
a first source/drain region formed in the semiconductor substrate adjacent to the first gate;
a second source/drain region formed in the semiconductor substrate adjacent to the first gate, wherein the first source/drain region and the second source/drain region are in electrical contact with each other; and
a first contact region disposed over the first source/drain region, wherein the first contact region is formed as a first plurality of segments, and wherein a first inter-segment gap separates a segment of the first plurality of segments from an adjacent segment of the first plurality of segments.

2. The semiconductor structure of claim 1, further comprising:
a second gate formed on the semiconductor substrate; and
a second contact region disposed over the first source/drain region, such that three contact regions are disposed between the first gate and the second gate, and wherein the second contact region is formed as a second plurality of segments, wherein a second inter-segment gap separates a segment of the second plurality of segments from an adjacent segment of the second plurality of segments.

3. The semiconductor structure of claim 2, wherein the first inter-segment gap of the first contact region is staggered in a non-overlapping configuration with the second inter-segment gap of the second contact region.

4. The semiconductor structure of claim 2, further comprising:
a third contact region disposed over the first source/drain region, such that two contact regions are disposed between the first gate and the second gate, and wherein the third contact region is formed as a third plurality of segments, wherein a third inter-segment gap separates a segment of the third plurality of segments from an adjacent segment of the third plurality of segments.

5. The semiconductor structure of claim 1, wherein the first inter-segment gap ranges from about 20 nanometers to about 300 nanometers.

6. The semiconductor structure of claim 1, wherein the first inter-segment gap ranges from about 15 nanometers to about 250 nanometers.

7. The semiconductor structure of claim 1, wherein the first inter-segment gap ranges from about 35 nanometers to about 500 nanometers.

8. The semiconductor structure of claim 1, wherein each segment of the first contact region ranges from about 80 nanometers to about 1200 nanometers.

9. The semiconductor structure of claim 1, wherein the first gate has a length that ranges from about 250 nm to about 5000 nm.

10. The semiconductor structure of claim 9, wherein the first gate comprises an N-type work function metal, and the semiconductor substrate comprises at least one of an N-well region or a P-well region disposed below the first gate.

11. The semiconductor structure of claim 9, wherein the first gate comprises a P-type work function metal, and the semiconductor substrate comprises at least one of a P-well region or N-well region disposed below the first gate.

12. A semiconductor structure comprising:
an array comprising a plurality of capacitor structures formed on a semiconductor substrate and arranged in an alternating pattern comprising a first capacitor type and a second capacitor type, wherein the first capacitor type and second capacitor type each comprise:
a first gate formed on the semiconductor substrate;
a first source/drain region formed in the semiconductor substrate adjacent to the first gate;
a second source/drain region formed in the semiconductor substrate adjacent to the first gate, wherein the first source/drain region and the second source/drain region are in electrical contact with each other;
a first contact region disposed over the first source/drain region, wherein the first contact region is formed as a first plurality of segments, wherein a first inter-segment gap separates a segment of the first plurality of segments from an adjacent segment of the first plurality of segments; and wherein the first capacitor type comprises an N-type work function metal, and wherein the first capacitor type comprises an N-well region disposed below the first gate; and
wherein the second capacitor type comprises a P-type work function metal, and wherein the second capacitor type comprises a P-well region disposed below the second gate.

13. The semiconductor structure of claim 12, further comprising a plurality of metallization lines oriented at a diagonal angle to the first gate, wherein a first metallization line of the plurality of metallization lines connects the first gate of a plurality of capacitors of the first capacitor type; and wherein a second metallization line of the plurality of metallization lines connects the first gate of a plurality of capacitors of the second capacitor type.

14. The semiconductor structure of claim 13, wherein the diagonal angle is a 45 degree angle.

15. The semiconductor structure of claim 12, wherein each capacitor structure of the plurality of capacitor structures comprises:
a second gate formed on the semiconductor substrate; and
a second contact region disposed over the first source/drain region, such that two contact regions are disposed between the first gate and the second gate, and wherein the second contact region is formed as a second plurality of segments, wherein a second inter-segment gap separates a segment of the second plurality of segments from an adjacent segment of the second plurality of segments.

16. The semiconductor structure of claim 12, wherein the first inter-segment gap ranges from about 20 nanometers to about 300 nanometers.

17. The semiconductor structure of claim 12, wherein the first inter-segment gap ranges from about 15 nanometers to about 250 nanometers.

18. The semiconductor structure of claim 12, wherein the first inter-segment gap ranges from about 35 nanometers to about 500 nanometers.

19. The semiconductor structure of claim 12, wherein each segment of the first contact region ranges from about 80 nanometers to about 1000 nanometers.

20. A semiconductor structure comprising:
an array comprising a plurality of capacitor structures formed on a semiconductor substrate and arranged in an alternating pattern comprising a first capacitor type and a second capacitor type, wherein the first capacitor type and second capacitor type each comprise:
a first gate formed on the semiconductor substrate;
a first source/drain region formed in the semiconductor substrate adjacent to the first gate;
a second source/drain region formed in the semiconductor substrate adjacent to the first gate, wherein the first source/drain region and the second source/drain region are in electrical contact with each other;
a first contact region disposed over the first source/drain region, wherein the contact region is formed as a plurality of segments, wherein an inter-segment gap separates a segment of the plurality of segments from an adjacent segment of the plurality of segments; and wherein the first capacitor type comprises an N-type work function metal, and wherein the first capacitor type comprises an N-well region disposed below the first gate; and wherein the second capacitor type comprises a P-type work function metal, and wherein the second capacitor type comprises a P-well region disposed below the second gate, and wherein at least one row or column of the array is comprised of dummy capacitor structures.
